(19) United States
(12) Patent Application Publication
(10) Pub. No.: US 2020/0312713 A1
(43) Pub. Date: Oct. 1, 2020

(54) MICROSTRUCTURING FOR ELECTROPLATING PROCESSES

(71) Applicant: SUSS MICROTEC PHOTONIC SYSTEMS INC., Corona, CA (US)

(72) Inventors: Habib HICHRI, Irvine, CA (US); Markus ARENDT, Corona, CA (US); Seongkuk LEE, Corona, CA (US)

(73) Assignee: SUSS MICROTEC PHOTONIC SYSTEMS INC.

(21) Appl. No.: 16/828,866

(22) Filed: Mar. 24, 2020

Related U.S. Application Data
(60) Provisional application No. 62/823,515, filed on Mar. 25, 2019.

(51) Int. Cl. H01L 21/768; H01L 21/02

(52) U.S. Cl. CPC H01L 21/76873; H01L 21/76879; H01L 21/0259

(57) ABSTRACT

A method for patterning and filling features on a substrate includes forming a patterned dielectric layer on a substrate; forming an array of microvias in portions of the patterned dielectric layer where a feature is larger than or equal to a critical size; depositing a seed layer on the patterned dielectric layer, including the array of microvias; electroplating a metal layer on the seed layer that is on the array of microvias; and removing portions of the seed layer where no metal layer is electroplated.

### CROSS-REFERENCE TO RELATED APPLICATIONS

This application claims priority to and the benefit of U.S. Provisional Patent Application No. 62/823,515 filed Mar. 25, 2019 and entitled “MICROSTRUCTURING FOR ELECTROPLATING PROCESSES”, which is hereby incorporated by reference in its entirety.

### BACKGROUND

### Technical Field

This application relates to techniques for fabricating electronics substrates and semiconductor wafers in general, and more particularly, for example, to methods for patterning and filling redistribution layers on such substrates and wafers using a microstructuring technique without the need to perform planarization.

### Related Art

As electronic devices become smaller and more sophisticated, the challenge of expanding capabilities while minimizing the space, or “footprint,” used by an integrated circuit has continued to increase. Techniques for reducing the space used by a semiconductor package include the use of a redistribution layer (RDL) as an additional level of wiring to reposition input and output (I/O) contact locations from the perimeter or center of the active surface to alternative locations.

There is a need to cut costs related to building RDLs for advanced packaging or back end of line structuring, and to find ways to shrink the form factor of the RDL lines to allow a higher I/O density, without compromising the electrical and thermal performance of the package. Shrinking the form factor of the RDL lines below 2/2 μm line/space (L/S) creates several major technical challenges, such as electro-migration between the lines, or difficulty in removing the seed layer between the lines without affecting the integrity of the lines.

In a conventional redistribution structure, RDL lines or traces may be embedded into a dielectric material on a surface of a semiconductor die. Typically, the lines or traces are formed on a dielectric layer, and another dielectric layer is then formed over the lines or traces, where the ends of the lines or traces at the redistributed contact locations remain exposed for subsequent disposition or formation of discrete conductive elements thereon.

In another approach, commonly termed a dual damascene process, the RDL lines or traces and vias may be deposited into recesses formed in a dielectric layer consecutively, followed by seed layer deposition and plating. The dual damascene process allows the lines to be embedded in a dielectric to prevents electro-migration, provides better thermal package performance, and removes the requirement for seed layer removal. One major drawback of the dual damascene process, however, is the need to perform chemical mechanical planarization (CMP) to remove the excess metal after plating. This process step is costly and presents a barrier to the adoption of the dual damascene process in advanced packaging.

Accordingly, there is a need for improved methods for the creation and filling of RDLs.

### SUMMARY

In accordance with one or more embodiments of the present invention, systems and methods are provided for patterning and filling RDLs that may avoid or reduce the above and other drawbacks of the prior art.

According to one embodiment of the present invention, a method for patterning and filling features on a substrate includes forming a patterned dielectric layer on a substrate; forming an array of microvias in portions of the patterned dielectric layer where a feature is larger than or equal to a critical size; depositing a seed layer on the patterned dielectric layer, including the array of microvias; electroplating a metal layer on the seed layer that is on the array of microvias; and removing portions of the seed layer where no metal layer is electroplated.

According to another embodiment of the present invention, a method for patterning and filling features on a substrate includes forming a dielectric layer on a substrate; patterning the dielectric layer with features larger than, equal to, and smaller than a critical size; patterning the features larger than or equal to the critical size with an array of microvias; depositing a seed layer on the patterned dielectric layer, including the array of microvias; electroplating a metal layer on the seed layer that is on the array of microvias; and removing portions of the seed layer where no metal layer is electroplated.

According to yet another embodiment of the present invention, a method for patterning and filling a feature on a substrate includes forming a first dielectric layer on a substrate; patterning the first dielectric layer with vias; patterning areas of the patterned first dielectric layer where redistribution layer (RDL) lines will be larger than a critical size with an array of microvias; depositing a second dielectric layer on the patterned first dielectric layer, including the array of microvias; patterning the second dielectric layer with openings for the RDL lines; depositing a seed layer over the patterned first and second dielectric layers, including the vias and the array of microvias; electroplating a metal layer on the seed layer that is on the vias and the array of microvias; and removing portions of the seed layer where no metal layer is electroplated.

A better understanding of the above and other features and advantages of the systems and methods of the present invention can be made from a consideration of the detailed description of some example embodiments thereof below, particularly if such consideration is made in conjunction with the appended drawings, wherein like reference numerals are used to identify like elements illustrated in one or more of the figures thereof.

### BRIEF DESCRIPTION OF THE DRAWINGS

FIG. 1 is a flowchart of a method of patterning and filling a feature on a substrate in accordance with an embodiment of the present invention;

FIGS. 2A-2F are cross-sectional side views of a substrate subjected to the method of patterning and filling a feature in accordance with FIG. 1 of the present invention;

FIG. 3 is a flowchart of another method of patterning and filling a feature on a substrate in accordance with an embodiment of the present invention;

FIGS. 4A-4H are cross-sectional side views of a substrate subjected to the method of patterning and filling a feature in accordance with FIG. 3 of the present invention;

FIGS. 5A-5E illustrate various stages of a wafer subjected to the method of patterning and filling a feature in accordance with an embodiment of the present invention; and

FIG. 6 illustrates a block diagram of a system for patterning and filling a feature on a substrate in accordance with an embodiment of the present invention.

### DETAILED DESCRIPTION

A microstructuring technique that allows same rate bottom-up plating of multiple features with different sizes without a need to perform planarization is provided. The present methods allow control of the plating speed across the whole surface to be plated so that no planarization is needed.

Plating baths may be characterized by the diameter or size of the feature that the bath can plate at a uniform rate. As used herein, “critical size” means the size of a feature that a plating bath is capable of plating at a constant rate. This critical size typically depends on the characteristics of the plating bath, such as the molecular size and type of plating bath additives. Features that are larger than the critical size, however, cannot be plated by the plating bath using conventional techniques. As used herein, “features” refer to holes, vias, trenches, and other openings formed in the plating surface.

The microstructuring methods create small features that roughen the bottom of a feature larger than the critical size. Creation of these small features enable same rate plating using bottom-up plating or other suitable plating methods. By enabling a same plating rate, a similar plating height can be obtained for all the patterned features across the substrate. In other words, the microstructuring methods enables similar plating height independent of the size of the feature, thereby eliminating current expensive planarization methods such as CMP to remove excess metal.

Advantageously, the microstructuring methods are applicable to any methods used for patterning vias and/or trenches for semiconductor devices and advanced packaging processes. In certain embodiments, the small features are patterned through use of laser ablation (e.g., excimer laser ablation), photolithography, direct laser writing, or other advanced patterning method.

Exemplary embodiments of the present invention will now be described with reference to the accompanying drawings.

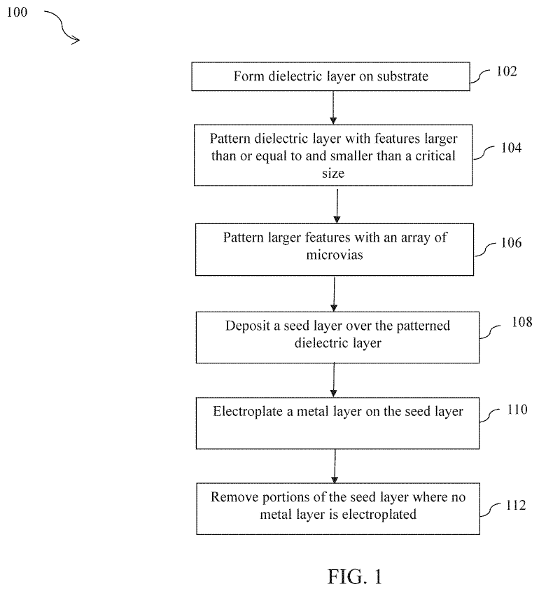

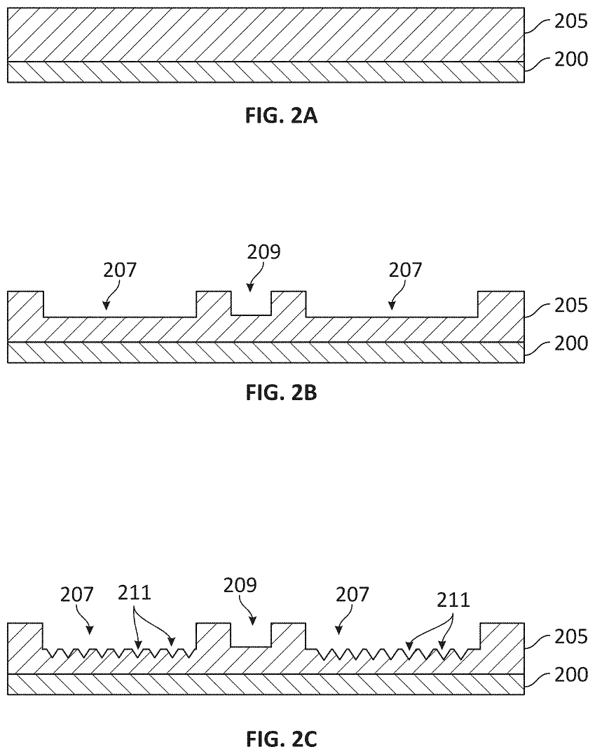

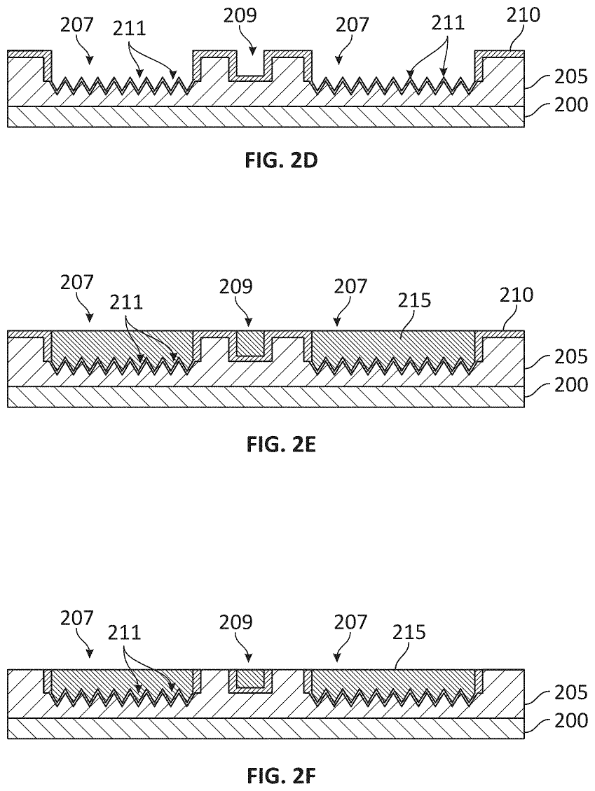

Referring to FIGS. 1 and 2A-2F, a method 100 for patterning and filling a feature on a substrate is described. At step 102 and FIG. 2A, a dielectric layer 205, or other material that can be patterned by laser (such as metal or glass) is formed on a substrate 200. For example, dielectric layer 205 may be formed on substrate 200 using a spinning operation. Substrate 200 can be any article to be electroplated such as a semiconductor wafer upon which integrated circuits are fabricated. For example, the substrate 200 may be a complementary metal-oxide-semiconductor (CMOS) wafer. Suitable dielectrics and patterning materials are known to one of ordinary skill in the art.

At step 104 and FIG. 2B, the dielectric layer 205 is patterned with features that are larger than or equal to a critical size and features that are smaller than a critical size. As shown, the dielectric layer 205 is patterned to include features 207 that have a diameter or size larger than or equal to the critical size (“larger feature”) and a feature 209 that is smaller than the critical size 209 (“smaller feature”). In some embodiments, the critical size is about 10 μm. Thus, a feature that is larger than the critical size would have a diameter or size greater than or equal to 10 μm, and a feature that is smaller than the critical size would have a diameter less than 10 μm.

In various embodiments, the dielectric layer 205 is exposed to beams from a UV laser to form a pattern (e.g., vias and/or trenches) through a mask or reticle, such that all areas of the dielectric layer 205 to be ablated are scanned by the beams. In some embodiments, a 193 nm, 248 nm, 308 nm, or 355 nm UV excimer laser is used, such as where mask scanning or spot shot ablation is used. The laser beams are absorbed by the dielectric layer 205, and the exposed regions of the dielectric layer 205 are ablated.

The use of laser ablation provides control over the depth of the material removed by selection of the number of pulses and the fluence (i.e., laser energy per unit area). Ablation depth is also determined by the absorption depth of the dielectric layer 205 and the heat of vaporization of the dielectric layer 205.

At step 106 and FIG. 2C, the larger features 207 are patterned with an array of microvias 211 using any suitable patterning technique (e.g., laser ablation, lithography, or laser direct imaging). In one embodiment, laser ablation is used to pattern the microvias 211 into the larger features 207. For example, while the substrate 200 is still on the ablation tool, a mask (e.g., the same mask used in step 104 or a new mask) designed with the array of microvias 211 are ablated into all of the larger features 207. To obtain microvias 211 with the desired depth and diameter, the ablation parameters of fluence and number of pulses are selected. Typically, a high fluence of greater than about 800 mJ/cm² and 3-4 pulses provide excellent results, depending on the ablation rate of the dielectric layer 205. In some embodiments, the fluence rate is about 500 to about 1500 mJ/cm², such as about 700 to about 1200 mJ/cm². After the microvias 211 are formed, the patterning process is continued by ablating vias that are needed to form the contact to the pad and/or RDL underneath.

In several embodiments, the surface of the larger features 207 are incrementally divided into an array of microvias 211, where the microvias have a diameter of greater than or equal to 1 μm, a spacing of less than or equal to 3 μm, and a depth of less than or equal to 2 μm. Generally, the geometry of the microvia array is dependent on the dimension of the larger features 207 to be microstructured. The larger the microstructured feature is, the bigger the microvias are and the larger the spacing between the microvias is. By microstructuring the larger features, the features larger than the critical size are divided into microvias that are within the critical size, thus allowing plating of all the features of the substrate at a uniform rate, without planarization.

At step 108 and FIG. 2D, a seed layer 210 is deposited over the patterned dielectric layer 205. The seed layer 210 is typically a thin layer of copper that may be sputtered onto the dielectric layer 205. The function of the seed layer 210 is to allow electric current to be distributed across substrate 200 thereby facilitating electroplating.

Any suitable method for seed layer deposition may be used, including chemical vapor deposition (CVD) or physical vapor deposition (PVD). PVD techniques include, for example and without limitation, techniques such as evaporation and various sputtering techniques, such as DC and/or RF plasma sputtering, bias sputtering, magnetron sputtering, ion plating, or Ionized Metal Plasma (IMP) sputtering. CVD techniques include, for example and without limitation, thermal CVD, Plasma Enhanced CVD (“PECVD”), Low Pressure CVD (“LPCVD”), High Pressure CVD (“HPCVD”), and Metal Organo CVD (“MOCVD”). In various embodiments, the seed layer 210 is about 0.02 μm to about 0.2 μm thick.

At step 110 and FIG. 2E, a metal layer 215 is electroplated on the seed layer 210. In several embodiments, the entire substrate 200 is submerged into a bath of ionic solution containing metal (e.g., copper) ions and an electroplating process causes a metal layer 215 to be formed on the seed layer 210 in the larger features 207 and the smaller features 209. As shown, the metal layer 215 fills the microvias 211.

Typical electroplating baths will contain the metal to be plated and its associated anions in an acid solution. Copper electroplating is generally performed from a solution of cupric sulfate (CuSO₄) dissolved in an aqueous solution of sulfuric acid. In addition to these major constituents of the plating bath, it is common for plating baths to contain several additives. “Additives” as used herein mean any type of compound added to the plating bath to change the plating behavior. Additives are typically, but not exclusively, organic compounds. Generally, additives are present in low concentrations in the plating bath. Additive concentrations in the range of parts-per-million (ppm) are, for example 20 to 400 ppm.

There are two general types of plating bath additives that may be added to the plating bath. Suppressor additives retard the plating reaction, increasing the polarization. Typical suppressors may be large molecules (for example, polymers) that may have an ionic end group, for example a surfactant. Increasing the surface polarization layer prevents the copper from adsorbing onto the surface. Suppressors can thus function as blockers. Suppressors cause the resistance of the surface to be very high in comparison to the electrolyte diffusion or electrical resistance.

Accelerator additives (catalysts) accelerate the plating reaction. Accelerators may be rather small molecules, generally containing sulfur and need not be ionic. Accelerators absorb onto the surface and increase the current. Accelerators may occur not as the species directly added to the electroplating bath, but as breakdown products of such molecules. In either case, the net effect is to increase current flow and accelerate the reaction when such species are present (or become present through electrochemical breakdown).

In various embodiments, the electroplating in step 110 is a bottom-up filling process that makes use of additives that preferentially direct electroplating to the larger features 207 and the smaller feature 209. Generally, the term “bottom-up filling” defines a desirable deposition characteristic that fills a feature in a vertical direction from the base portion of the feature upwardly to the top portion of the feature without deposition growth in a horizontal direction within the feature and at the upper edge of the feature.

In some embodiments, the electroplating bath used in step 110 includes both suppressor additives and accelerator additives. Without being bound by theory, it is believed that the microvias 211 having small diameters and low depths house the accelerators and repulse the suppressors in the plating bath to enable a uniform plating rate in all the features across the substrate 200 that are smaller than the critical size. Thus, metal deposits preferentially on seed layer 210 at the base portions of larger features 207 and small feature 209, and deposits much slower on the seed layer 210 that is over unpatterned dielectric layer 205. It will be appreciated by those of ordinary skill in the art that other metal baths such as Ni, Au, Ag, Zn, Pd, Sn, etc. may be used in the methods of the present invention to provide metal plating baths and that copper is just one example. Advantageously, because deposition of metal layer 215 is directed to larger features 207 and small feature 209, no planarization methods such as CMP are required to remove excess metal from the dielectric layer 205.

At step 112 and FIG. 2F, portions of the seed layer 210 where no metal layer 215 is electroplated are removed using any suitable technique or combination of techniques known to those of ordinary skill in the art. For example, wet or dry etching techniques may be used to remove seed layer 210. In some embodiments, a laser is used to remove surplus seed layer 210.

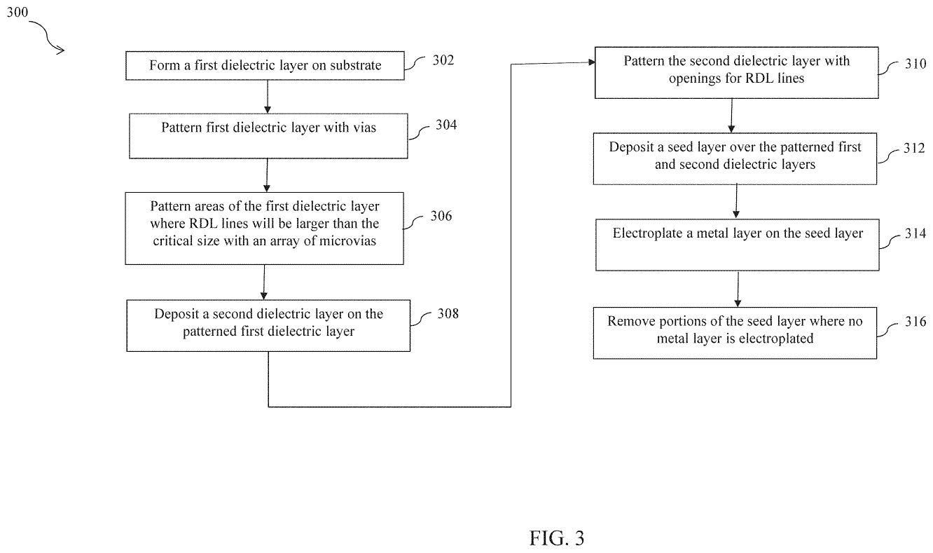

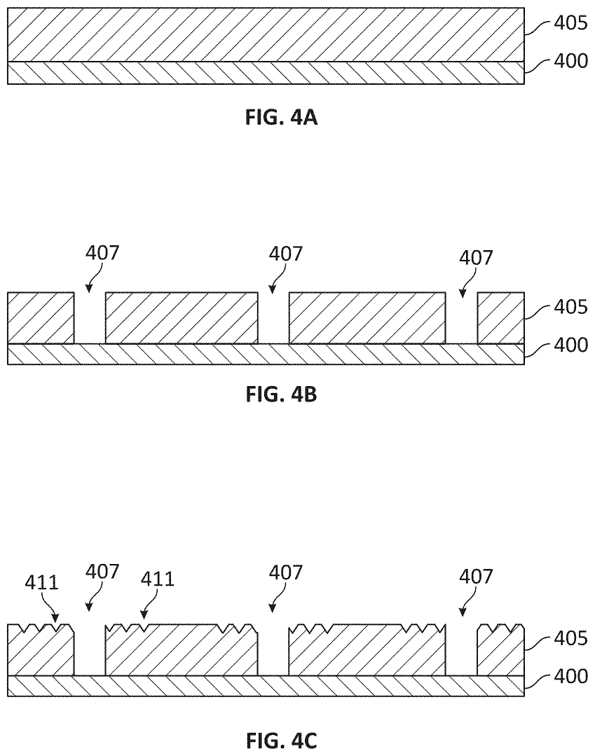

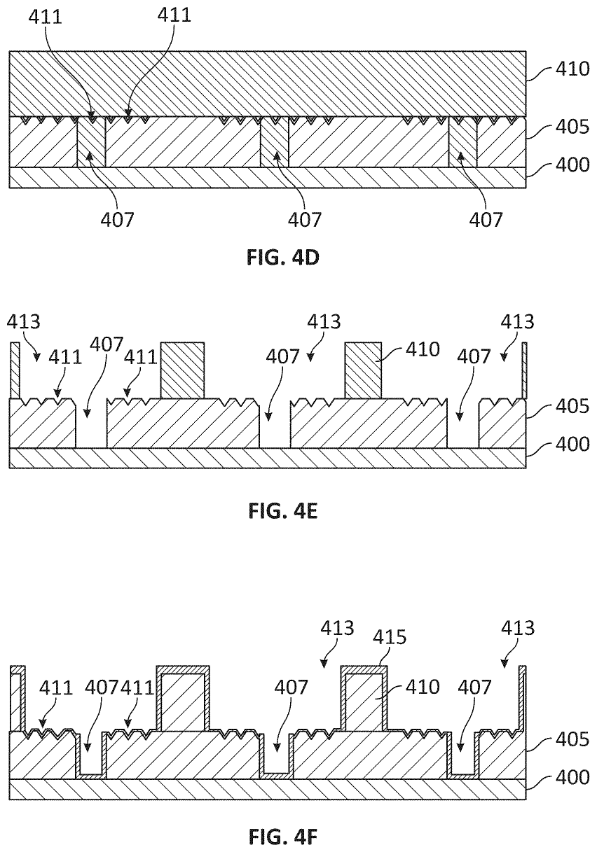

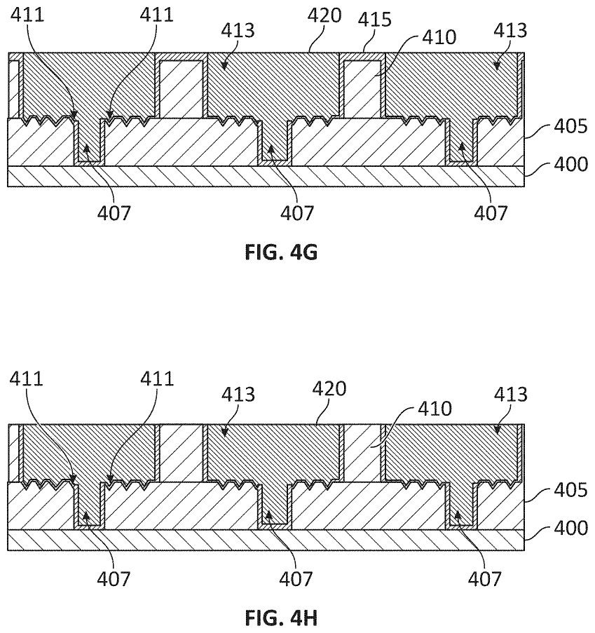

Referring now to FIGS. 3 and 4A-4F, another method 300 for patterning and filling a feature on a substrate is described. At step 302 and FIG. 4A, a first dielectric layer 405, or other material that can be patterned, is formed on a substrate 400. The substrate 400 may be any suitable substrate, such as a CMOS wafer. Suitable dielectrics and patterning materials are known to one of ordinary skill in the art.

At step 304 and FIG. 4B, the first dielectric layer 405 is patterned with vias 407 using any suitable technique, such as lithography or laser direct imaging. All vias 407, independent of their size, are patterned into the first dielectric layer 405. In some embodiments, the first dielectric layer 405 is patterned by lithography and etching processes to form vias 407 in the first dielectric layer 405. For example, a patterned photoresist layer may be formed on the first dielectric layer 405. The patterned photoresist layer includes various openings that define portions of the first dielectric layer 405 for vias 407 and expose those portions for subsequent etch. In one embodiment, the patterned photoresist layer is formed by a procedure including coating, exposure, and developing.

At step 306 and FIG. 4C, areas of the first dielectric layer 405 where RDL traces or lines will be larger than the critical size are patterned with an array of microvias 411 using any suitable patterning technique (e.g., laser ablation, lithography, or laser direct imaging). Step 306 is similar to step 106 described above. Once the microvias 411 are exposed, the substrate 400 is developed and undergoes subsequent processes such as full curing of the first dielectric layer 405.

At step 308 and FIG. 4D, a second dielectric layer 410 is deposited on the patterned first dielectric layer 405. As shown, the second dielectric layer 410 fills the vias 407 and the microvias 411.

At step 310 and FIG. 4E, the second dielectric layer 410 is patterned with openings 413 for RDL lines or traces using any suitable technique. For example, the second dielectric layer 410 is patterned by lithography and etching processes to form openings 413 in the second dielectric layer 410. In some embodiments, a patterned photoresist layer may be formed on the second dielectric layer 410. The patterned photoresist layer includes various openings that define portions of the second dielectric layer 410 for openings 413 and expose those portions for subsequent etch. Once the openings 413 are exposed, the substrate 400 is developed and undergoes subsequent processes such as full curing of the second dielectric layer 410.

At step 312 and FIG. 4F, a seed layer 415 is deposited over the patterned first and second dielectric layers 405 and 410. Step 312 is similar to step 108 discussed above.

At step 314 and FIG. 4G, a metal layer 420 is electroplated on the seed layer 415. Step 314 is similar to step 110 discussed above. As shown, the metal layer 420 fills the vias 407, the microvias 411, and the openings 413 to form RDLs.

At step 316 and FIG. 4H, portions of the seed layer 415 where no metal layer 420 is electroplated are removed. Step 316 is similar to step 112 discussed above.

### EXAMPLE

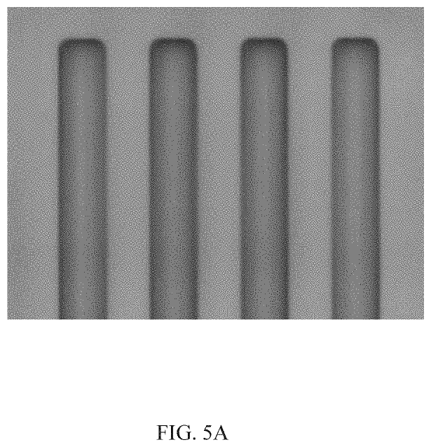

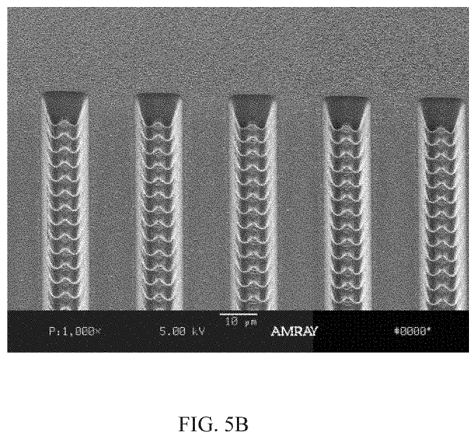

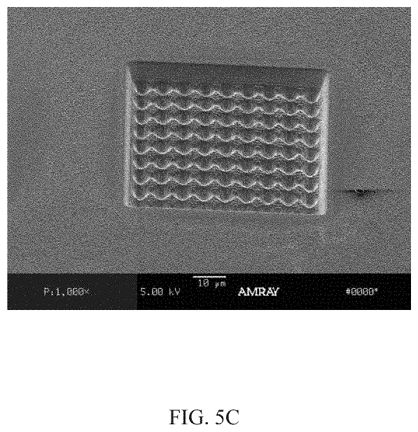

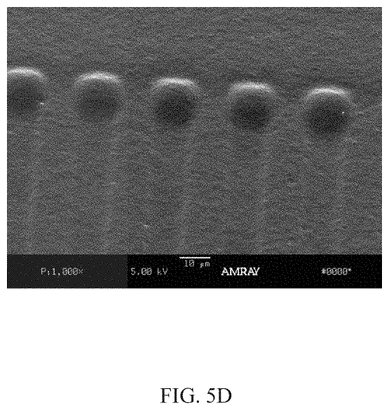

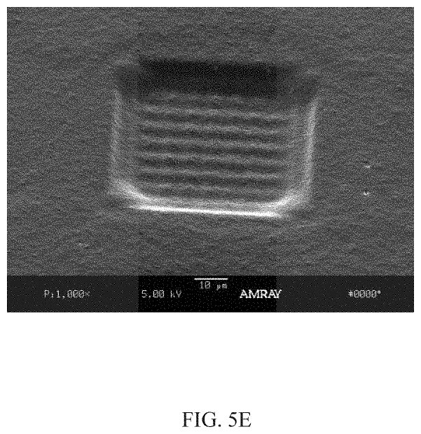

A wafer was coated and cured with the designated dielectric, and loaded into the excimer laser chuck. The excimer laser ablated the distribution layer and stopped at 1-2 μm before the required stop depth as shown in FIG. 5A. Then a new design either on the same mask or on a different mask was loaded and aligned, and the ablation of the microstructures was completed as shown in FIGS. 5B and 5C. This step ablates the microstructures and patterns the bottom of the large structure (>12 μm or pads: square) with vias ranging from 5-10 μm size with a depth of about 2-3 μm. In this example, the vias are about 8 μm with a depth of about 2.5 um. After ablation, the wafer is processed for copper barrier or seed layer sputtering (TiW/Ti/Cu or seed layer of Ti/Cu). In this example, only a seed layer was sputtered (100 μm Ti/200 μm Cu). The wafer was then plated using the bottom-up plating process as shown in FIGS. 5D and 5E.

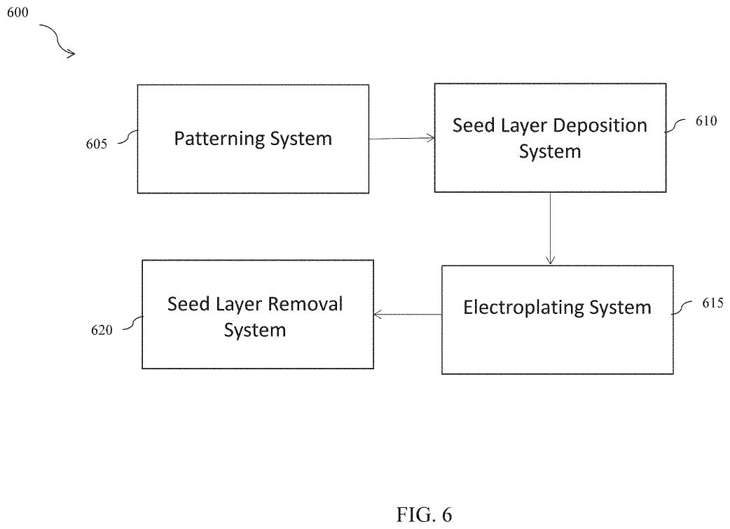

FIG. 6 illustrates a system 600 that may be used to pattern and fill a feature on a substrate in accordance with one or more embodiments. System 600 includes a patterning system 605, a seed layer deposition system 610, an electroplating system 615, and a seed layer removal system 620. Patterning system 600 patterns the dielectric layers 205, 405, and 410, and forms arrays of microvias 211 and 411 in the dielectric layers. In some embodiments, the patterning system 600 includes a laser ablation system that patterns the dielectric layers 205, 405, and 410 using a laser light source, for example, an excimer laser. In other embodiments, the patterning system 600 includes a photolithography system that patterns the dielectric layers 205, 405, and 410 using a mask, a photoresist layer, and UV light. Next, a seed layer 210 or 415 is deposited over the patterned dielectric layers 205, 405, and 410 in the seed layer deposition system 610. Seed layer deposition system 610 may include systems for CVD or PVD. Once the seed layer 210 or 415 is deposited, a metal layer 215 or 420 is deposited on the seed layer 210 or 415 in electroplating system 615. Finally, surplus seed layer 210 or 415 is removed in seed layer removal system 620.

As those of skill in this art will by now appreciate, many modifications, substitutions and variations can be made in and to the materials, apparatus, configurations and methods of patterning and filling features on a substrate in accordance with one or more embodiments of the present invention without departing from its spirit and scope. Accordingly, the scope of the present invention should not be limited to the particular embodiments illustrated and described herein, as they are merely by way of some examples thereof, but rather, should be fully commensurate with that of the claims appended hereafter and their functional equivalents.

What is claimed is:

1. A method for patterning and filling features on a substrate, comprising:
forming a patterned dielectric layer on a substrate;
forming an array of microvias in portions of the patterned dielectric layer where a feature is larger than or equal to a critical size;
depositing a seed layer on the patterned dielectric layer, including the array of microvias;
electroplating a metal layer on the seed layer that is on the array of microvias; and
removing portions of the seed layer where no metal layer is electroplated.

2. The method of claim 1, wherein forming the array of microvias comprises use of excimer laser ablation, photolithography, or direct laser writing, or wherein the critical size is about 10 μm.

3. The method of claim 1, wherein microvias in the array of microvias have a diameter of greater than or equal to 1 μm, a spacing of less than or equal to 1 μm, and a depth of less than or equal to 2 μm.

4. The method of claim 1, wherein the electroplating comprises a bottom-up filling process, and the bottom-up filling process uses a plating bath comprising suppressor additives and accelerator additives.

5. The method of claim 1, wherein no planarization is performed to remove portions of the seed layer.

6. A system for performing the method of claim 1, comprising:
a patterning system;
a seed layer deposition system;
an electroplating system; and
a seed layer removal system.

7. A method for patterning and filling features on a substrate, comprising:
forming a dielectric layer on a substrate;
patterning the dielectric layer with features larger than, equal to, and smaller than a critical size;
patterning the features larger than or equal to the critical size with an array of microvias;
depositing a seed layer on the patterned dielectric layer, including the array of microvias;
electroplating a metal layer on the seed layer that is on the array of microvias; and
removing portions of the seed layer where no metal layer is electroplated.

8. The method of claim 7, wherein patterning the features larger than the critical size with an array of microvias comprises use of laser ablation, and the use of laser ablation comprises use of a fluence rate of about 500 to about 1500 mJ/cm² and 3-4 pulses.

9. The method of claim 7, wherein the critical size is about 10 μm.

10. The method of claim 7, wherein microvias in the array of microvias have a diameter of greater than or equal to 1 μm, a spacing of less than or equal to 1 μm, and a depth of less than or equal to 2 μm.

11. The method of claim 7, wherein the electroplating comprises a bottom-up filling process, and the bottom-up filling process uses a plating bath comprising suppressor additives and accelerator additives.

12. The method of claim 7, wherein no planarization is performed to remove portions of the seed layer.

13. A system for performing the method of claim 7, comprising:
a patterning system;
a seed layer deposition system;
an electroplating system; and
a seed layer removal system.

14. A method for patterning and filling a feature on a substrate, comprising:
forming a first dielectric layer on a substrate;
patterning the first dielectric layer with vias;
patterning areas of the patterned first dielectric layer where redistribution layer (RDL) lines will be larger than a critical size with an array of microvias;
depositing a second dielectric layer on the patterned first dielectric layer, including the array of microvias;
patterning the second dielectric layer with openings for the RDL lines;
depositing a seed layer over the patterned first and second dielectric layers, including the vias and the array of microvias;
electroplating a metal layer on the seed layer that is on the vias and the array of microvias; and
removing portions of the seed layer where no metal layer is electroplated.

15. The method of claim 14, wherein the critical size is about 10 μm.

16. The method of claim 14, wherein microvias in the array of microvias have a diameter of greater than or equal to 1 μm, a spacing of less than or equal to 1 μm, and a depth of less than or equal to 2 μm.

17. The method of claim 14, wherein the electroplating comprises a bottom-up filling process.

18. The method of claim 17, wherein the bottom-up filling process uses a plating bath comprising suppressor additives and accelerator additives.

19. The method of claim 14, wherein no planarization is performed to remove portions of the seed layer.

20. A system for performing the method of claim 14, comprising:
a patterning system;
a seed layer deposition system;
an electroplating system; and
a seed layer removal system.
